(19) United States
(12) Patent Application Publication
(10) Pub. No.: US 2024/0126954 A1
(43) Pub. Date: Apr. 18, 2024

(54) SYSTEM FOR AND METHOD OF CALCULATING HYDROLOGICAL CONDITIONS USING MACHINE LEARNING

(71) Applicant: True Elements, Inc., Naples, FL (US)

(72) Inventors: William C. LOUISELL, III, Mt. Pleasant, SC (US); David BANKSTON, Naples, FL (US)

(21) Appl. No.: 18/379,547

(22) Filed: Oct. 12, 2023

Related U.S. Application Data
(60) Provisional application No. 63/415,831, filed on Oct. 13, 2022.

(51) Int. Cl. G06F 30/27; G06F 30/28

(52) U.S. Cl. CPC G06F 30/27; G06F 30/28

(57) ABSTRACT

Systems and methods for calculating and predicting hydrological conditions using machine learning to modify hydrological condition algorithms over time. A system can generate, using a first hydrology model for a predefined hydrologic unit, a runoff volumetric forecast, and execute a transport model of the predefined hydrologic unit, resulting in a first hydrograph. The system can receive a flow volumetric report for the predefined hydrologic unit and execute the transport model of the predefined hydrologic unit using the flow volumetric report, resulting in a second hydrograph. The system can also receive a flow volumetric forecast for the predefined hydrologic unit and generate a third hydrograph of the predefined hydrologic unit using the flow volumetric forecast as input. The system can then compare the hydrographs to one another, resulting in a short term correction matrix, and modify the first hydrology model based on the short term correction matrix.

### CROSS-REFERENCE TO RELATED APPLICATIONS

This application claims priority to U.S. Provisional Application No. 63/415,831, filed Oct. 13, 2022, the entire contents of which are hereby incorporated by reference.

### BACKGROUND

### 1. Technical Field

The present disclosure relates to calculating and predicting hydrological conditions, and more specifically to the use of machine learning to modify hydrological condition algorithms over time.

### 2. Introduction

Identifying and calculating current hydrological conditions for a given area, and predicting what future hydrological conditions will be, is critical to sustainable agriculture, accurate weather prediction, meaningful analysis of climate change effects.

### SUMMARY

Additional features and advantages of the disclosure will be set forth in the description that follows, and in part will be understood from the description, or can be learned by practice of the herein disclosed principles. The features and advantages of the disclosure can be realized and obtained by means of the instruments and combinations particularly pointed out in the appended claims. These and other features of the disclosure will become more fully apparent from the following description and appended claims, or can be learned by the practice of the principles set forth herein.

Disclosed are systems, methods, and non-transitory computer-readable storage media which provide a technical solution to the technical problem described. A method for performing the concepts disclosed herein can include: generating, via at least one processor of a computer system using a first hydrology model for a predefined hydrologic unit, a runoff volumetric forecast; executing, via the at least one processor, a transport model of the predefined hydrologic unit, resulting in a first hydrograph; receiving, at the computer system, a flow volumetric report for the predefined hydrologic unit; executing, via the at least one processor, the transport model of the predefined hydrologic unit using the flow volumetric report, resulting in a second hydrograph; receiving, at the computer system, a flow volumetric forecast for the predefined hydrologic unit; generating, via the at least one processor, a third hydrograph of the predefined hydrologic unit using the flow volumetric forecast as input; comparing, via the at least one processor, the first hydrograph, the second hydrograph, and the third hydrograph to one another, resulting in a short term correction matrix; and modifying, via the at least one processor, the first hydrology model based on the short term correction matrix.

A system configured to perform the concepts disclosed herein can include: at least one processor; and a non-transitory computer-readable storage medium having instructions stored which, when executed by the at least one processor, cause the at least one processor to perform operations comprising: generating, using a first hydrology model for a predefined hydrologic unit, a runoff volumetric forecast; executing a transport model of the predefined hydrologic unit, resulting in a first hydrograph; receiving a flow volumetric report for the predefined hydrologic unit; executing the transport model of the predefined hydrologic unit using the flow volumetric report, resulting in a second hydrograph; receiving a flow volumetric forecast for the predefined hydrologic unit; generating a third hydrograph of the predefined hydrologic unit using the flow volumetric forecast as input; comparing the first hydrograph, the second hydrograph, and the third hydrograph to one another, resulting in a short term correction matrix; and modifying the first hydrology model based on the short term correction matrix.

A non-transitory computer-readable storage medium configured as disclosed herein can have instructions stored which, when executed by at least one processor, cause the at least one processor to perform operations which include: generating, using a first hydrology model for a predefined hydrologic unit, a runoff volumetric forecast; executing a transport model of the predefined hydrologic unit, resulting in a first hydrograph; receiving a flow volumetric report for the predefined hydrologic unit; executing the transport model of the predefined hydrologic unit using the flow volumetric report, resulting in a second hydrograph; receiving a flow volumetric forecast for the predefined hydrologic unit; generating a third hydrograph of the predefined hydrologic unit using the flow volumetric forecast as input; comparing the first hydrograph, the second hydrograph, and the third hydrograph to one another, resulting in a short term correction matrix; and modifying the first hydrology model based on the short term correction matrix.

### BRIEF DESCRIPTION OF THE DRAWINGS

FIG. 1 illustrates an example hydrology tree;

FIG. 2 illustrates an example of different flow models being used in parallel to generate hydrographs;

FIG. 3 illustrates an example of calculating differences between generated hydrographs to calculate short-term model corrections and long-term model corrections;

FIG. 4 illustrates an example of updating short-term and long-term models;

FIG. 5 illustrates examples of different types of data blending;

FIG. 6 illustrates an example of blending a subordinate data set with a dominant data set;

FIG. 7. illustrates an example of determining a blending ratio;

FIG. 8a illustrates an example of resolving uncertainty with blended data;

FIG. 8b illustrates an example of confirming potential classifications;

FIG. 9 illustrates an example of path tracing;

FIG. 10 illustrates an example method embodiment; and

FIG. 11 illustrates an example of a computer system.

### DETAILED DESCRIPTION

Various embodiments of the disclosure are described in detail below. While specific implementations are described, this is done for illustration purposes only. Other components and configurations may be used without parting from the spirit and scope of the disclosure.

One of the major challenges in understanding water quality and quantity at scale (i.e., regionally, state-wide, and nation-wide) is resolution of cases where there are gaps in data, cases where there is contradictory overlap of data derived from multiple sources, and/or a lack of availability of specific water quality data. This challenge is further compounded when the objective is to understand water quality and quantity in near-real time and/or in the future. Understanding variability in water quality (even at specific geo-spatial points) due to daily weather conditions, seasonal climate patterns, agricultural crop cycles, and variation in socio-economic patterns of life is important to all water consumers due to the effects on human health, industrial processes, agricultural use, and the near-, mid-, and long-term environmental impacts.

Furthermore, various major disruptions to the afore-mentioned patterns occur in the form of natural and/or man-made events, such as flooding, drought, forest fires, extreme storms, and/or earth displacement (e.g., earthquakes, dam failures, landslides, etc.) which can generate significant short-term temporary changes, intermediate-term persistent conditions, and/or permanent changes in one or more water quality metrics. On top of these water quality variation drivers, there are longer term changes taking place in terms of climate change and continuously evolving land use patterns.

Systems configured as disclosed herein address these challenges using a variety of specific methods to resolve data sparsity, data ambiguity, and data scarcity. These systems are specifically designed to meet the water quality and quantity information needs of a range of stakeholders (federal, state, and local government agencies; major commercial enterprises; and those interested in socio-economic risk and resiliency). The systems can use iterative machine learning to improve the ability to forecast hydrological conditions for a given area. More specifically, systems can compare short and long-term forecasts with sensor data and National Water Model (NWM) forecasts, then update the short and long-term forecasting algorithms based on differences detected. This process can iterate overtime, such that the short and long-term forecasts become more accurate, but also automatically adapt to evolving climate conditions.

Data used by systems configured as disclosed herein can use data from local data sources, such as local hydrological and meteorological sensors, local databases, etc. The data can also be provided by government services. Exemplary government services from which the systems can retrieve data can include: the National Water Information System (NWIS), which is a web application providing access to real-time and historical surface-water, groundwater, water-quality, and water-use data at millions of sites across all fifty states; the National Oceanic and Atmospheric Administration (NOAA), which is a U.S. government agency which forecasts weather, monitors oceanic and atmospheric conditions, charts the seas, conducts deep sea exploration, and manages fishing and protection of marine mammals and endangered species in the U.S. exclusive economic zone. In addition, the Environmental Protection Agency (EPA) publishes data related to all National Pollution Discharge Elimination System (NPDES) in the form of Discharge Monitoring Reports (DMR) and the Toxic Release Inventory System (TRIS). These reports identify point and non-point sources, location of the discharge/release, the various constituents, and loading levels on a periodic basis. Outside the U.S. similar data may be obtained from government and/or private sources.

Systems configured as disclosed herein can use the data from multiple locations to build separate models based on the data received and the geographic areas associated with the data. The system can then compare the predictions of these separate models and identify both short and long-term modifications which, if applied to one or more of the models, will result in improved accuracy of the models.

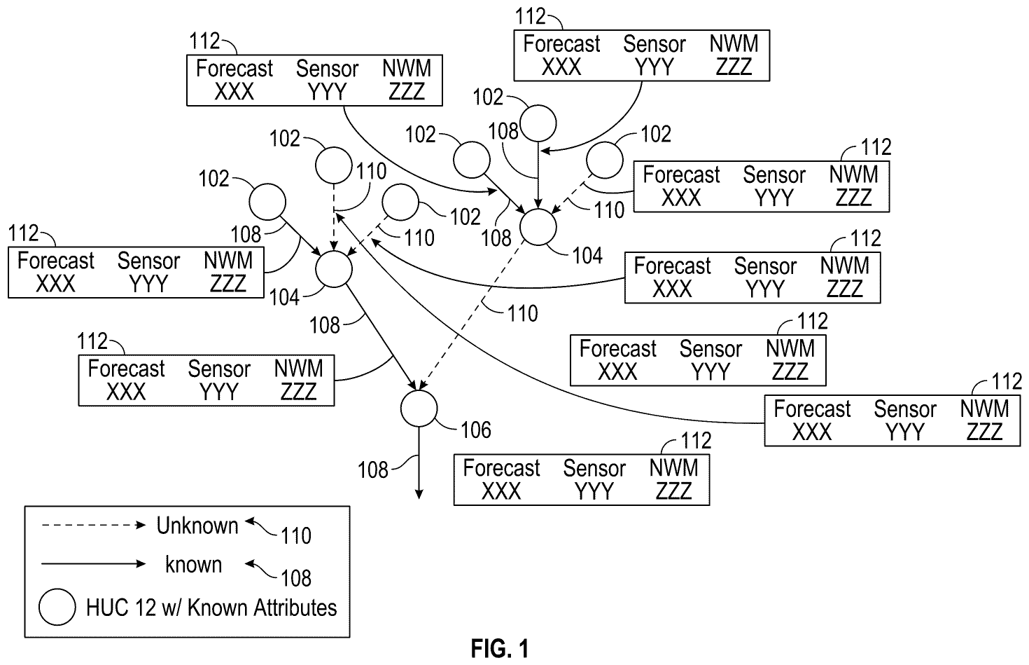

One of the key elements of understanding water quality at any specific point is understanding the hydrology of the area of interest. FIG. 1 illustrates an example hydrology/hydrography tree. Each circle 102, 104, 106, or node, within the tree represents a HUC (Hydrologic Unit Code). HUCs are geographic areas within a geographic area which are divided and sub-divided into successively smaller hydrologic units. For example, the United States is divided and sub-divided into four levels: regions, subregions, accounting units, and cataloging units. The hydrologic units are nested within each other, from the largest geographic area (regions) to the smallest geographic area (cataloging units), with each hydrologic unit being identified by a unique hydrologic unit code (HUC). In the United States, these codes consisting of two digits (for regions) to eight digits (for the cataloging units) based on the four levels of classification in the hydrologic unit system. In other countries or geographic areas, different types of codes can be used to define hydrologic units. For example, within the U.S., a HUC 12 is the smallest geographic unit (a cataloging unit), and is called a HUC 12 because there are 12 digits used to identify the hydrological unit, which has predefined geographic boundaries. A HUC 10 would be the next larger region, and would be made up of several HUC 12s. HUC 8s are made of multiple HUC 10s, and so forth.

Within the illustration, the water in a HUCs flows downstream, such that water from one hydrologic region flows into a distinct hydrologic region. Thus, the solid arrows 108 and the dashed arrows 110 within the figure illustrate water flowing from region to region. However, while the amount of water transferred between some regions is known (illustrated by the solid arrows 108 between nodes), in other cases the amount of water transferred between regions is unknown (illustrated by the dashed arrows 110 between nodes). In such cases where the amount of water is unknown, predicting the amount of water transferred as a result of the hydrologic conditions in both respective regions (the upstream and downstream regions) can be difficult to predict. Systems configured according to the principles and concepts disclosed herein can predict, with increased accuracy, the resulting hydrologic conditions despite the lack of known transfer between regions.

As illustrated, a given HUC can have associated with it three different pieces of sensor data 112: sensor and/or discharge/release data, a National Water Model (NWM) report on the level of flows, and/or a forecast of the level of flows. The sensor data 112 can include real-time sensor data from sensors located within the geographic boundaries of the HUC, and can also include previous sensor data collected from that HUC. For example, the sensor data may be collected by sensors and periodically transmitted to a computer system which records the data for sensors and/or discharge/release reports within that HUC (e.g., every 10 minutes, every hour, every day, etc.). This “live” or real time data can be refreshed according to the desired category (e.g., current water level, average water level over the past hour, average water level over the past day, etc.), such that the system can delete old or outdated data which is older than a desired threshold. In some configurations the central computer system may also maintain data regarding previously recorded data, such as data collected yesterday, last week, last month, etc., as well as aggregations of such data.

The National Water Model (NWM) data is a hydrologic modelling framework that simulates observed and forecast streamflow over the entire continental United States (CONUS), and is generated by the Office of Water Prediction (OWP) within the National Oceanic and Atmospheric Administration (NOAA) of the United States government. The NWM simulates the water cycle with mathematical representations of the different processes, how they fit together, and outputs hydrological guidance for the various HUCs.

Also associated with each HUC is a forecast. The forecast represents both short-term and long-term hydrological predictions for the HUC based on models formed using the systems and methods disclosed herein. Because of the interconnected nature of the HUCs, a forecast of a single HUC can have an impact on a neighboring HUC, and vice versa. Over time, using the machine learning techniques described herein, the algorithms for short-term and long-term forecasts can be updated based on differences detected between the NWM guidance, the sensor data, and the system's forecasts (both short-term and long-term).

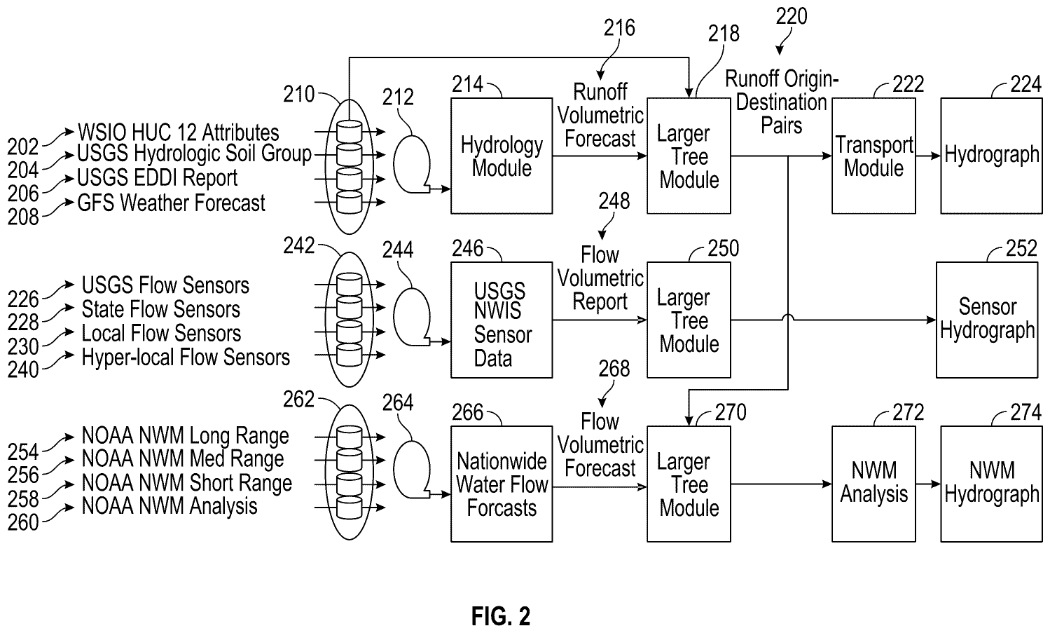

FIG. 2 illustrates an example of different flow models being used in parallel to generate hydrographs. Within the illustration, those models/modules 214, 218, 222, 224 are elements of the system disclosed herein, while the larger tree module (or modules) 218, 250, 270 are used by the system in analyzing data received from exterior sources. Other models/modules can vary according to configuration (e.g., in some configurations they may be elements of the system, whereas in other configurations they may be provided by a third party). This data (from exterior sources) can be normalized spatially and temporally such that it can readily and selectively be used in conjunction with the forecast data to serve as a basis for continuous calibration. As illustrated, data can be used for the forecasting mechanisms performed by the system can include watershed data, soil data, drought data, and weather forecast data. Exemplary watershed data can include WSIO (Watershed Index Online, a watershed database operated by the U.S. Environmental Protection Agency), can be used to obtain HUC attributes, resulting in WSIO HUC 12 Attributes 202. An example of soil data for the geographic region/HUC can include resources such as the USGS (United States Geographical Survey) hydrologic soil group 204, which can provide an index of the rate that water infiltrates a soil. As an example of drought data, the system can use the USGS EDDI (Evaporative Demand Drought Index) report 206 to obtain near-real-time data regarding agricultural drought, hydrologic drought, and fire-weather risk, or on the emergence or persistence of anomalous evaporative demand in a region. As an example of weather forecast data, the system can use a GFS (Global Forecast System) weather forecast 208 to receive data such as forecasted surface pressure and precipitation amounts. The received weather forecast data 210 can then be aggregated together 212 and input into a model operated by the system (illustrated as the “Hydrology Module 214), resulting in a Runoff Volumetric Forecast 216 describing the amount of runoff predicted for a given HUC over a given period of time. This Runoff Volumetric Forecast 216 can, in some cases, be used with the Runoff Volumetric Forecasts of multiple HUCs and the watershed, soil, drought, and weather forecast data 210 to model a larger geographic area (using a larger model algorithm/larger tree module 218, such as a HUC 8 model if the original areas were HUC 12s), with the result being Runoff Origin-Destination Pairs 220 (e.g., a water source location where runoff is originating and a second location where the runoff will arrive/passthrough). The Runoff Origin-Destination Pairs 220 can then be input into a transport module 222, which models how much water will flow and how fast the water will flow from point-to-point within the larger area, resulting in a system hydrograph 224 (the illustrated hydrograph 224) which is a continuous hydrograph).

Sensor data from multiple sources can also be collected to create a composite 244 compilation of received sensor data 242. Exemplary types of sensor data can include USGS flow sensors 226 associated with the HUC, State (or province) flow sensors 228, Local (such as city or county) flow sensors 230, and hyper-local flow sensors (such as a specific address, street, or individual sensor location) 240. Once the received sensor data 242 is compiled together 244, the resulting composite, “live” sensor data 246 creates a Flow Volumetric Report 248. The Flow Volumetric Report 248 can then be input into a larger area model 250 (which can be the same larger tree model 218, or a different larger area model) used to obtain the Runoff Origin-Destination pairs 220, with this output resulting in a sensor hydrograph 252. Unlike the hydrograph 224, this sensor hydrograph 252 is periodic based on when sensor data 242 is received, resulting in gaps within the sensor hydrograph 252 because of gaps between instances when the sensor data 242 was collected. Accounting for these gaps in sensor data 242 coverage is one of the benefits of systems configured as described herein. Further, an additional benefit of systems configured as described herein is the ability to relate the landcover and land use properties of the contributing watershed area such that the water quality impacting constituents expected within the runoff generated by precipitation events can be identified and quantified. This capability, not previously executable at scale and in near real-time, is a cornerstone of transitioning from an environment in which water quality events are identified in retrospect to one in which water quality events are forecast and thereby potentially mitigated and/or eventually minimized/eliminated.

The system can also receive NOAA National Weather Model (NWM) data 262, such as long range data 254, medium range data 256, short range data 258, and analysis 260. The NOAA NWM data 262 can be combined 264 together, resulting in one or more Nation-wide Water Flow Forecasts 266. The Nationwide Water Flow Forecasts 266 can include a Flow Volumetric Forecast 268. When the Flow Volumetric Forecast 268 is input into a larger area model 270 (e.g., the same larger area model 218, 250 as used for the other hydrographs or a different model), it results in a NWM analysis 272 and a NWM hydrograph 274 which, like the system hydrograph 224, is continuous.

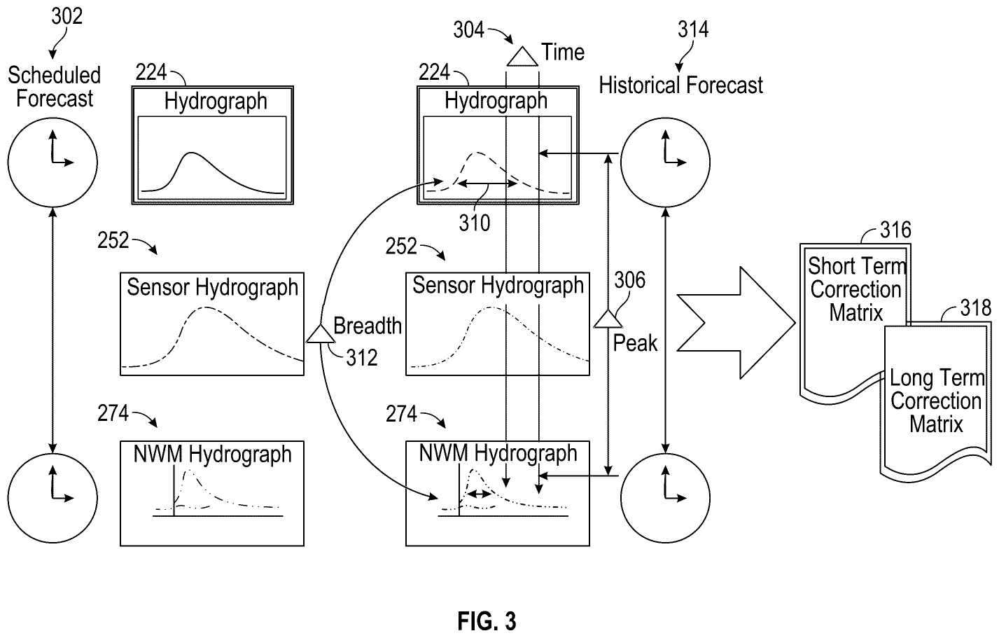

FIG. 3 illustrates an example of calculating differences between generated hydrographs 224, 252, 274 to calculate short-term model corrections 316 and long-term model corrections 318. As illustrated, the hydrographs (hydrograph 224, the sensor hydrograph 252, and the NWM hydrograph 274) are the hydrographs created and described in FIG. 2. Similar to FIG. 2, the hydrograph 224 is the produced by the system disclosed herein, while other hydrographs/models/modules can vary according to configuration (e.g., in some configurations they may be elements of the system, whereas in other configurations they may be provided by a third party). The system compares the hydrographs 224, 252, 274 to one another, identifying differences (represented by the delta symbol) such as different amplitudes from baseline levels (e.g., different peak values 306 or low values), different times 304 for different events (e.g., how long water levels were above a certain amplitude within each model), different breadths 312, and/or total volume 310 within one or more periods of time (e.g., the amount of water under the illustrated curves). The arrows illustrated are solely to represent differences found between the respective hydrographs. As illustrated, the detected differences are between the hydrograph 224 and the NWM hydrograph 274, however in practice the differences can be between any and/or all of the hydrographs 224, 252, 274.

Based on the differences identified by the comparison, the system can create short-term model corrections 316 and long-term model corrections 318 which correct how the system's forecasting predicts short-term and long-term forecasts. The data to generate those corrections can be based on scheduled forecasts 302 and/or historical forecasts 314. For example, the short-term correction matrix 316 can be used to modify weights, code, or other aspects of the short-term forecast algorithm (e.g., an algorithm that can predict hydrological conditions over a predefined period of time, such as five days, a week, three weeks, etc.), such that the code used for that algorithm is updated based on the differences detected. Likewise, the long-term forecast algorithm (e.g., an algorithm that can predict hydrological conditions over a longer period of time than the short-term forecast algorithm, such as twenty-five years) can receive updates based on the differences detected.

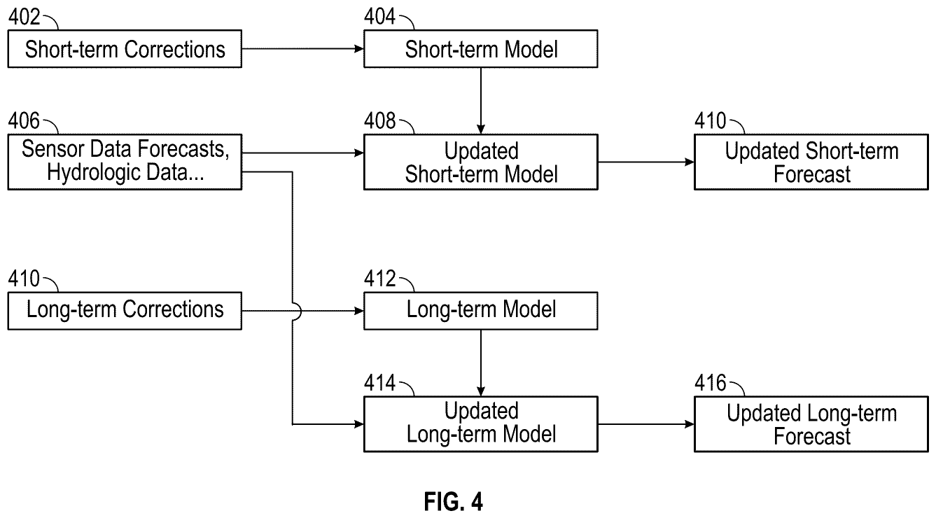

FIG. 4 illustrates an example of updating short-term and long-term models. As illustrated, the short-term corrections 402 and the long-term corrections 410 are applied to the short-term model 404 and the long-term model 412 (that is, the short-term corrections 402 are applied to the short-term model 404, and the long-term corrections 410 are applied to the long-term model 412). In some configurations, the data (such as the sensor data, the forecasts, the hydrological data) which led to the different hydrographs can also be used to update the short-term 404 and long-term models 412. The updated short-term model 408 and the updated long-term model 414 are then saved in the system's memory, with the result that in future iterations short-term forecasts are made using sensor data forecasts and hydrologic data 406 with the updated short-term model 408, and long-term forecasts are made using sensor data forecasts and hydrologic data 406 with the updated long-term model 416.

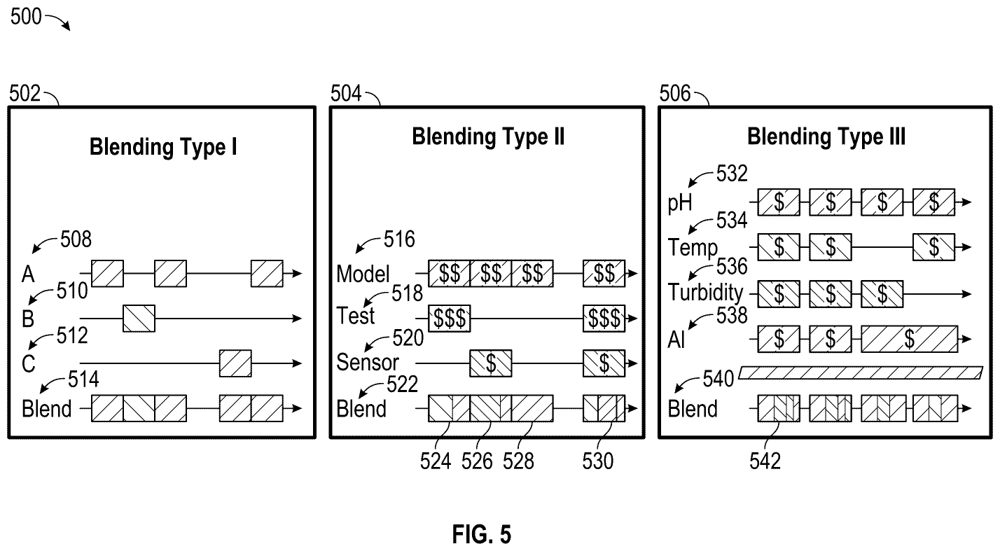

FIG. 5 illustrates examples of different types of data blending 500. A general description of the data blending methods 502, 504, 506, with descriptions of the methods accompanying the figures, is provided, followed by more detailed explanation for the data blending methods. Broadly, the first data blending method (Blending Type I) 502 identifies different data streams (A 508, B 510, and C 512) and seeks to combine data from those data streams in a manner which synchronizes the data and fills in any missing data using additional sensor data. As illustrated, the resulting blend 514 has portions of A 508, portions of B 510, and portions of C 512. However, in first data blending method 502 the portions of the data streams 508, 510, 512 do not overlap, such that the portions selected for the blend 514 match the corresponding data stream 508, 510, 512 which has data at a given time, if any.

The second data blending method (Blending Type II) 504 adds onto the first data blending method by using a model (such as an AI model) to predict missing sensor data. As illustrated, the model provides a model data stream 516 generated using the original data streams A 508, B 510, and C 512 used in first data blending method 502. However, in this case, executing the model has costs (symbolized by the use of $$ symbols in the illustration). The second data blending method 504 also has a data stream for test data 518, which can be used to verify that the model is operating correctly. Additional sensor data 520 can be provided, with the system then generating a blended data stream 522 which is a mix of available data for a given time period. As illustrated, the first block 524 in the blended data stream 522 is a mixture of the model data stream 516 and the test data stream 518. The second block 526 is a mixture of the model data stream 516 and the sensor data stream 520. The third block 528 is a copy of the model data stream 516 for that portion, and the final block 530 is a mixture of the model data stream 516, the test data stream 518, and the sensor data stream 520.

The third data blending method (Blending Type III) 506 further adds to the second data blending method 504 by further analyzing the water to categorize any potential events and, if necessary, perform path tracing on the body of water to determine the source of any contamination. While the combination system used to generate the blended data stream 540 for the third blending type is similar to (or the same as) the blending used in the second data blending method 504, the additional data can include pH data 532, temperature data 534, turbidity data 536, and/or AI data 538 (which can be, for example, the blended data stream 522 of the second data blending method 504). The resulting blended data stream 540 combines the available data streams 532, 534, 536, 538. For example, the first block 542 in the blended data stream 540

First Data Blending Method 502

The first data blending method 502 is dedicated to three functions. First, a query specific geo-spatial point is identified as the landing point for all relevant data that may be collected from multiple, non-overlapping data sources. Within this function, differences in geo-spatial and/or temporal reference points are resolved and normalized to provide a consistent reference for all subsequent higher-level uses of the data.

Next, incoming data is tagged to identify its: location of reference, time of reference, originating source, time of collection if known, time of release and/or revision, and an indication of the data as provisional or final. A vector tagging system can indicate downstream computational utility, reflecting the interactions the water will have with quality and/or quality influences during the vertical movement from the atmosphere to the earth's surface, then along the (vertical) path from infiltration to soil layers into groundwater stores (e.g., aquifers) and/or along a (horizontal) path from one watershed to the next via overland and/or riverine flow.

Finally, the multi-source, now normalized data can be used for pre-structured or ad hoc visualizations/reports that provide key insights into the quality and quantity of influencing mass exchanges, such as in the case of contaminants and volume exchanges, or in the case of discharges into and/or retrievals from the overland/riverine flows that take place at each point along the water journey from raindrop to the sea. In cases where a desired data feature is missing, this first data blending method examines all relevant sources, identifying the degree to which a multiple data sources will be combined to generate the complete visualization and/or report noting that, in some cases, there will be missing elements that are reflected in the user interface as not available.

Second Data Blending Method 504

The second data blending method 504 builds upon the first data blending method 502 in the data development sequence. Here, the available data is assessed to identify cases where there is more than one input to a particular data need. Exemplary inputs include: federal agency sponsored adjudicated sensor data; outputs from a federal agency developed, adjudicated model; locally sponsored non-adjudicated sensor data; specific state, local government, or university sponsored water sample lab testing; citizen scientist organization members that conduct hyper-local sampling for lab testing; citizen scientist organization members that conduct field testing. To adjudicate across such a wide variety of data sources, the second data blending method employs a three-step process.

First, the second data blending method 504 executes a data precedence determination algorithm that ranks data based at least one of: agency precedence; presence of originator adjudication indication; data veracity as determined by a specialized algorithm that scores data history, data continuity, and data consistency; and evaluation of statistical significance of the smaller data set.

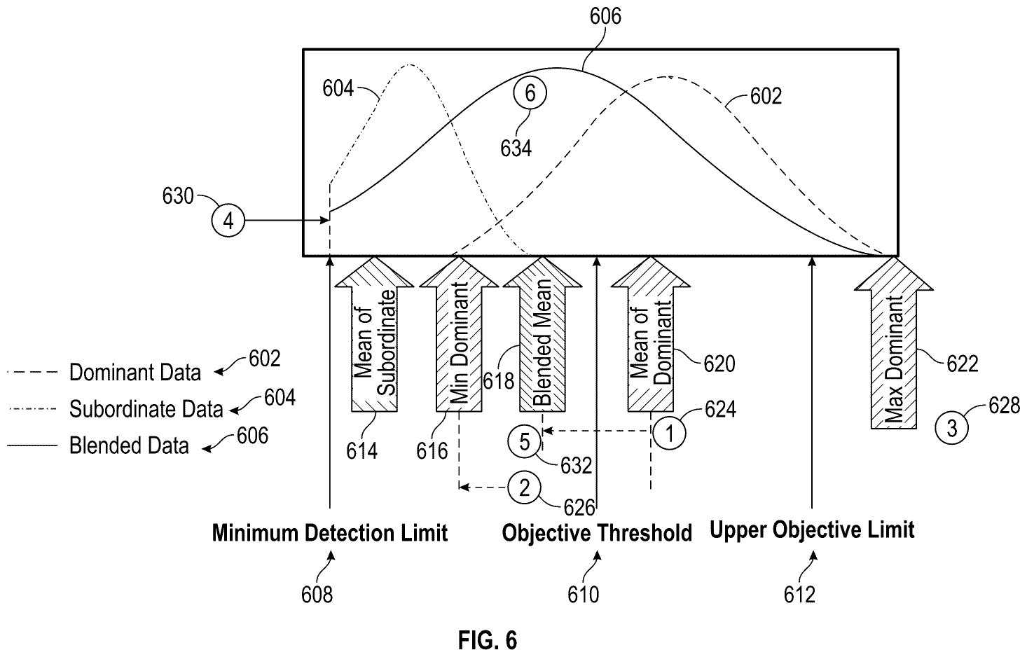

Second, with the candidate data sets scored according to these parameters (agency precedence, originator adjudication, veracity, and statistical significance), the second data blending method 504 selects an applicable blending rule from a specialized table of rules. The rules provide a progressive guide to determine three key features. FIG. 6 illustrates an example of blending a subordinate data set 604 with a dominant data set 602, resulting in blended data 606, and the key features of the rules.

Rule Feature One is the determination of offset direction (i.e., higher or lower) from the mean value of the higher precedence data (dominant) towards the mean value of lesser precedence data (subordinate) (FIG. 6, Item (1)) 624.

Rule Feature Two is the selection of an offset position limit within the range of combined observations which are expressed in the algorithm as a constraint that considers the contribution of the subordinate data while respecting the precedence of the dominate data (FIG. 6, Item (2)) 626. With the direction of offset and the limit of offset determined, the third feature is implemented.

Rule Feature Three addresses the degree of influence that the subordinate data set can have on the dominant data set (FIG. 6, Item (3)) 628. This influence is determined by first testing for statistical significance. As a prerequisite, the data sets (subordinate and dominate) are checked for and brought into congruence (e.g., aligning them based on a minimum detection limit 608, corresponding to FIG. 6, Item (4)) 630 with respect to constraints related to detection and reporting limits (FIG. 6, Item (5)) 632. With statistical significance determined, the second element of Rule Feature Three is to determine the Size and Data Density Ratios between the subordinate and dominate data sets.

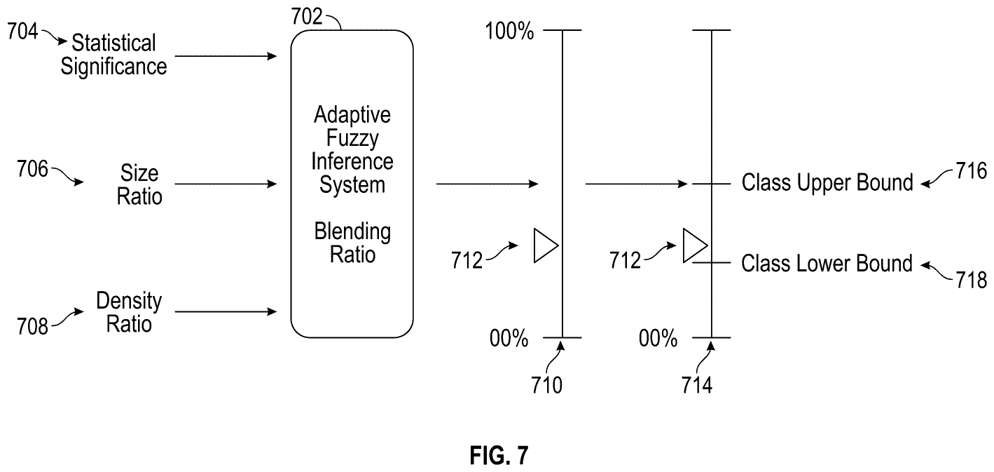

The third part of the second data blending method 504 includes executing assessments of statistical significance, data size ratio, and data density ratio. These are performed by an adaptive fuzzy inference system which determines the blending ratio as a value between 0% to 100%, with the value representing the degree to which the dominant data shifts toward the subordinate data. From initial startup, the adaptive fuzzy inference system dynamically refines its initial seed antecedent, consequence values, and relationship rules as observations are gathered and various classes (subordinate to dominate) relationships emerge. This learning quality enables the user to assess the scenario being considered in context with other similar observations within a class, such as drinking water or contaminants (relying on the US EPA Primary and Secondary Drinking Water Regulations, the US EPA Unregulated Contaminant Monitoring Reports, the US EPA Toxic Release Inventory, the US EPA Discharge Monitoring Reported Constituents, Agricultural Nutrients, Agricultural Herbicides, Agricultural Pesticides, Agricultural Fungicides, EPA monitored Wastewater Discharge Guidelines, and other emerging contaminants of national, regional, or local interest). FIG. 7. illustrates an example of determining a blending ratio. As illustrated, the Adaptive Fuzzy Inference System 702 receives information regarding statistical significance 704, the size ratio 706, and the density ratio 708 of data received. The Adaptive Fuzzy Inference System 702 uses data such as the statistical significance 704, the size ratio 706, and the density ratio 708, to determine how the data being blended should be combined, with the ratio (i.e., the result) 712 (produced at time 710) identifying-how much of each type of data should be included in the resulting blended data stream 522. This result has a class upper boundary 716 and a class lower boundary 718, and, if necessary, can be updated over time (as illustrated by the ratio 712 produced at time 710 and time 714).

Once the blending ratio is determined, the blended data set mean is calculated via the example formula illustrated in FIG. 6, Item (5) 632. This value serves as the anchor point for imputing a blended data distribution illustrated in FIG. 6, Item (6) 634. Left and right tails (also called termini) are set, and the apparent shape of the dominant data distribution (Normal, Poisson, Erlang, etc.) can be applied. Useful data which can be applied by the second data blending method 504 and used in the blending can include the minimum detection limit 608, the upper objective limit 612, the objective threshold 610, the mean of the subordinate data 614, the minimum point of the dominate data 616, the blended mean 618, the mean of the dominant data 620, and/or the maximum point of the dominant data 622. The metadata developed in the second data blending method 504 can be stored by geo-spatial point, by imputation time stamp, and/or by parameter of interest, providing a repository to support point and generalized learning to define the relationships between water quality and quantity in near-real time and/or in the future.

Third Data Blending Method 506

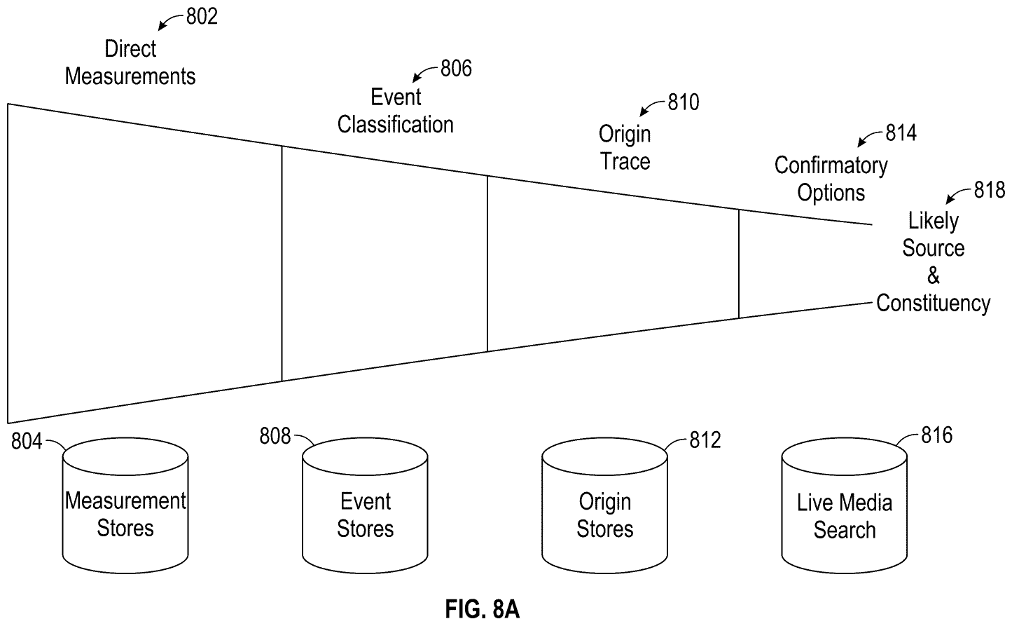

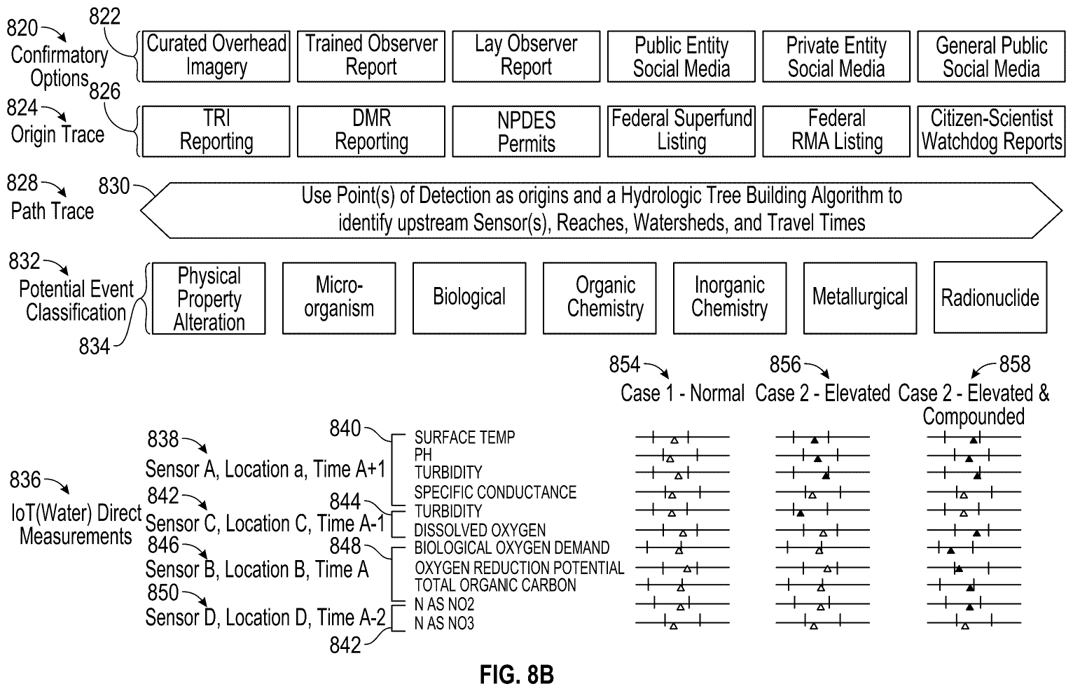

The third data blending method 506 further adds to the second data blending method 504 by further analyzing the water to categorize any potential events and, if necessary, perform path tracing on the body of water to determine the source of any contamination. As illustrated in FIG. 8a, resolution of uncertainty decreases using blended data as disclosed herein. For example, whereas there may be large amounts of uncertainty associated with direct measurements data 802 stored in measurement stores (e.g., databases), as the direct measurements data 802 (stored in measurement stores 804) is combined/blended with other types of the data the uncertainty can decrease (illustrated by the narrowing of the likely source & constituency 818 as more data is combined together). For example, events can be classified 806 based on similarity to previous events stored in event stores 808. Origins traces 810 of contaminants and other aspects of the water can be determined using data stored in origin stores 812, further reducing the uncertainty. Finally, the system can initiate confirmatory options 814 (such as doing a review of public/private social media, or other live media search 816, analyzing (e.g., through Natural Language Processing) observer reports, to confirm the conclusions reached to that point.

As illustrated in FIG. 8b, data associated with various bodies of water can be collected (bottom of the figure, case one 854 (showing normal), case two 856 (showing elevated), and case three 858 (showing elevated and compounded)). Data collected can, for example come from one or more sensors 838, 842, 846, 850, producing IoT (Internet of Things) direct measurement data 836. The exemplary categories of data being collected can include (but are not limited to): (from sensor A 838) surface temperature, pH, turbidity, and specific conductance 840; (from sensor C 842) turbidity and dissolved oxygen 844; (from sensor B 846) biological oxygen demand, oxygen reduction potential, and total organic carbon 848; and (from sensor D 850) N (Nitrogen) detected as NO₂ and N detected as NO₃ 842. This data can be collected at a single time or, as illustrated, can be collected at different times as required by the sensors and the system configuration. The standard ranges for the collected data can be identified by the system based on historical data using standard deviation or other acceptable mechanisms to determine the upper and lower limits of a given range. The first data blending method 502 can be used to collect the direct measurement data 836 from IoT (Internet of Things) sensors, private sensors, and/or public sensors, then fill in any missing data using the different data streams. The second data blending method 504 can then be used to provide various confirmatory options 820 by which the collected data can be confirmed. These confirmatory options 820 can include (but are not limited to): curated overhead imagery, trained observer report, lay observer report, public entity social media, private entity social media, and general public social media 822. Origin trace data 824 which can be used for the origin trace 810 can include (but is not limited to) TM (Toxic Release Inventory) reporting, DMRs (Discharge Monitoring Reports), NPDES (National Pollutant Discharge Elimination System) permits, Federal Superfund listings, Federal RMA (Risk Management Agency) listing, and Citizen-Scientist watchdog reports 826.

In addition to the confirmatory options via the second data blending method 504, the third data blending method 506 allows the system to classify any potential events based on the data collected and any confirmatory data. For example, if the pH of the water is determined to be elevated (while all of the other data points are within the normal range), the system may classify a likely problem as “X”, whereas if the pH of the water were elevated along with low turbidity, the system may classify the likely problem as “Y”. These classifications can be made using an AI engine (e.g., a neural network) which receives the different data points and outputs a predicted water classification. The neural network can be trained, for example, using data of known bodies of water and their known classifications.

Exemplary, non-limiting potential event classifications 832 can include: physical property alteration, micro-organism, biological, organic chemistry, inorganic chemistry, metallurgical, and/or radionuclide 834. In many cases there may be multiple potential classifications which are triggered based on the sensor readings, and the flags created by the system will be used by investigators to determine the type and reason why out-of-range data is being detected. That said, as the system collects additional data, the AI/neural network can be modified and/or retrained, such that the classification system becomes more accurate over time.

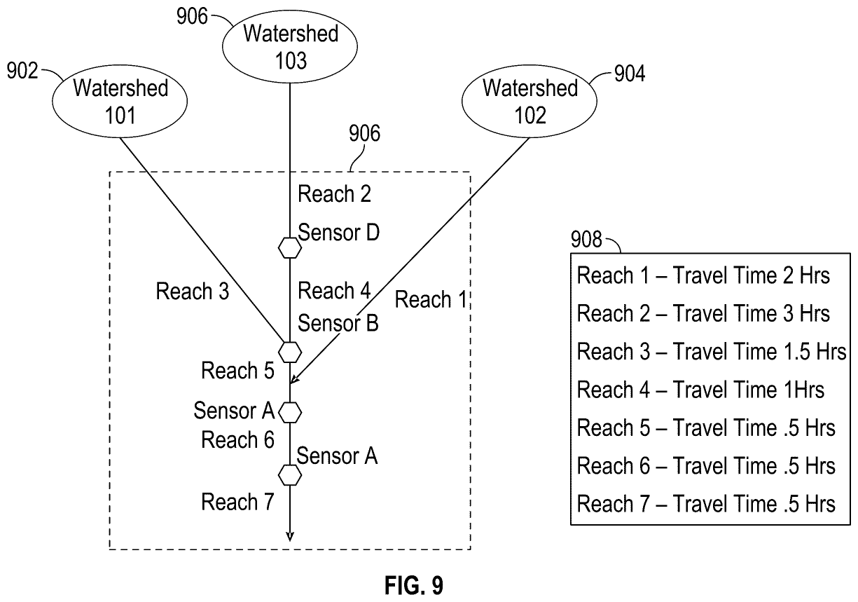

In addition to a classification of potential hydrological problems using AI, the third data blending method can cause the system to perform path tracing 828 and origin tracing 810 to determine the source of the detected problem. This can again be via an AI algorithm, using point(s) of detection as origin points and a hydrological tree model 910 of the watershed as inputs (operating, for example, as an N-dimension hypercube, with different features acting as weights for the different dimensions) to the AI algorithm, which can predict the origin of the problem as well as identify upstream sensor(s), reaches, watersheds 902, 904, 906, and travel times 908. (see FIG. 9).

In addition to the path tracing data 830, the system can use other public/private data sources, such as TM (Toxic Release Inventory) reporting, DMRs (Discharge Monitoring Reports), NPDES (National Pollutant Discharge Elimination System) permits, Federal Superfund listings, Federal RMA (Risk Management Agency) listing, and Citizen-Scientist watchdog reports 826, can be used by the system to identify the origin of potential problems. For example, using one or more public/private databases, the system can include the geographic coordinates of a known contaminant site with the hydrological model, such that the system can predict with greater accuracy the source of the contamination/problem.

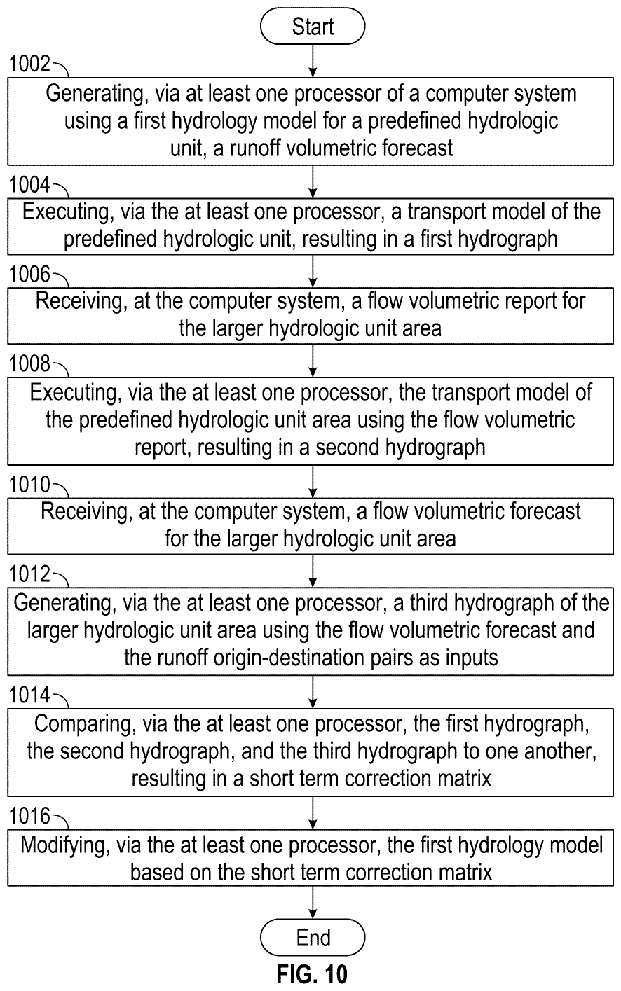

FIG. 10 illustrates an example method embodiment. As illustrated, the method can include generating, via at least one processor of a computer system using a first hydrology model for a predefined hydrologic unit, a runoff volumetric forecast (1002), and executing, via the at least one processor, a transport model of the predefined hydrologic unit, resulting in a first hydrograph (1004). The method can continue by receiving, at the computer system, a flow volumetric report for the predefined hydrologic unit (1006), and executing, via the at least one processor, the transport model of the predefined hydrologic unit using the flow volumetric report, resulting in a second hydrograph (1008), and receiving, at the computer system, a flow volumetric forecast for the predefined hydrologic unit (1010). The method can then include generating, via the at least one processor, a third hydrograph of the predefined hydrologic unit using the flow volumetric forecast as input (1012), and comparing, via the at least one processor, the first hydrograph, the second hydrograph, and the third hydrograph to one another, resulting in a short term correction matrix (1014). Then the method can include modifying, via the at least one processor, the first hydrology model based on the short term correction matrix (1016).

In some configurations, the comparing of the first hydrograph, the second hydrograph, and the third hydrograph to one another further results in a long term correction matrix. In such configurations, the method can further include modifying, via the at least one processor, a second level hydrology model based on the long term correction matrix.

In some configurations, the comparing of the first hydrograph, the second hydrograph, and the third hydrograph to one another can further include at least one of: identifying a distinct peak water level within the first hydrograph, the second hydrograph, and the third hydrograph; identifying a distinct breadth of water level within the first hydrograph, the second hydrograph, and the third hydrograph; and identifying a distinct water retreat time period within the first hydrograph, the second hydrograph, and the third hydrograph.

In some configurations, the flow volumetric report can be based on sensor data collected from a plurality of sensors, such that the second hydrograph is based on the sensor data. In such configurations, the first hydrograph and the second hydrograph can be continuous predictions of hydrologic conditions, and wherein the second hydrograph is periodic based upon collection of the sensor data.

In some configurations, the predefined hydrologic unit can be a HUC 8, HUC 10, HUC 12, or any other HUC.

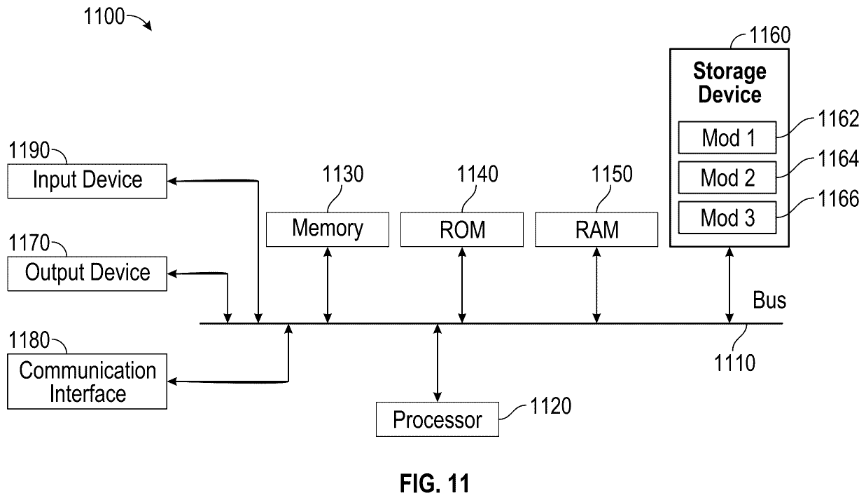

With reference to FIG. 11, an exemplary system includes a computing device 1100, including a processing unit (CPU or processor) 1120 and a system bus 1110 that couples various system components including the system memory 1130 such as read-only memory (ROM) 1140 and random-access memory (RAM) 1150 to the processor 1120. The computing device 1100 can include a cache of high-speed memory connected directly with, in close proximity to, or integrated as part of the processor 1120. The computing device 1100 copies data from the system memory 1130 and/or the storage device 1160 to the cache for quick access by the processor 1120. In this way, the cache provides a performance boost that avoids processor 1120 delays while waiting for data. These and other modules can control or be configured to control the processor 1120 to perform various actions. Other system memory 1130 may be available for use as well. The system memory 1130 can include multiple different types of memory with different performance characteristics. It can be appreciated that the disclosure may operate on a computing device 1100 with more than one processor 1120 or on a group or cluster of computing devices networked together to provide greater processing capability. The processor 1120 can include any general-purpose processor and a hardware module or software module, such as module 1 1162, module 2 1164, and module 3 1166 stored in storage device 1160, configured to control the processor 1120 as well as a special-purpose processor where software instructions are incorporated into the actual processor design. The processor 1120 may essentially be a completely self-contained computing system, containing multiple cores or processors, a bus, memory controller, cache, etc. A multi-core processor may be symmetric or asymmetric.

The system bus 1110 may be any of several types of bus structures including a memory bus or memory controller, a peripheral bus, and a local bus using any of a variety of bus architectures. A basic input/output (BIOS) stored in ROM 1140 or the like, may provide the basic routine that helps to transfer information between elements within the computing device 1100, such as during start-up. The computing device 1100 further includes storage devices 1160 such as a hard disk drive, a magnetic disk drive, an optical disk drive, tape drive or the like. The storage device 1160 can include software modules 1162, 1164, 1166 for controlling the processor 1120. Other hardware or software modules are contemplated. The storage device 1160 is connected to the system bus 1110 by a drive interface. The drives and the associated computer-readable storage media provide nonvolatile storage of computer-readable instructions, data structures, program modules and other data for the computing device 1100. In one aspect, a hardware module that performs a particular function includes the software component stored in a tangible computer-readable storage medium in connection with the necessary hardware components, such as the processor 1120, system bus 1110, output device (such as a display) 1170, and so forth, to carry out the function. In another aspect, the system can use a processor and computer-readable storage medium to store instructions which, when executed by a processor (e.g., one or more processors), cause the processor to perform a method or other specific actions. The basic components and appropriate variations are contemplated depending on the type of device, such as whether the computing device 1100 is a small, handheld computing device, a desktop computer, or a computer server.

Although the exemplary embodiment described herein employs the storage device 1160 (such as a hard disk), other types of computer-readable media which can store data that are accessible by a computer, such as magnetic cassettes, flash memory cards, digital versatile disks, cartridges, random access memory (RAM) 1150, and read-only memory (ROM) 1140, may also be used in the exemplary operating environment. Tangible computer-readable storage media, computer-readable storage devices, or computer-readable memory devices, expressly exclude media such as transitory waves, energy, carrier signals, electromagnetic waves, and signals per se.

To enable user interaction with the computing device 1100, an input device 1190 represents any number of input mechanisms, such as a microphone for speech, a touch-sensitive screen for gesture or graphical input, keyboard, mouse, motion input, speech and so forth. An output device 1170 can also be one or more of a number of output mechanisms known to those of skill in the art. In some instances, multimodal systems enable a user to provide multiple types of input to communicate with the computing device 1100. The communications interface 1180 generally governs and manages the user input and system output. There is no restriction on operating on any particular hardware arrangement and therefore the basic features here may easily be substituted for improved hardware or firmware arrangements as they are developed.

The technology discussed herein refers to computer-based systems and actions taken by, and information sent to and from, computer-based systems. One of ordinary skill in the art will recognize that the inherent flexibility of computer-based systems allows for a great variety of possible configurations, combinations, and divisions of tasks and functionality between and among components. For instance, processes discussed herein can be implemented using a single computing device or multiple computing devices working in combination. Databases, memory, instructions, and applications can be implemented on a single system or distributed across multiple systems. Distributed components can operate sequentially or in parallel.

Use of language such as “at least one of X, Y, and Z,” “at least one of X, Y, or Z,” “at least one or more of X, Y, and Z,” “at least one or more of X, Y, or Z,” “at least one or more of X, Y, and/or Z,” or “at least one of X, Y, and/or Z,” are intended to be inclusive of both a single item (e.g., just X, or just Y, or just Z) and multiple items (e.g., {X and Y}, {X and Z}, {Y and Z}, or {X, Y, and Z}). The phrase “at least one of” and similar phrases are not intended to convey a requirement that each possible item must be present, although each possible item may be present.

The various embodiments described above are provided by way of illustration only and should not be construed to limit the scope of the disclosure. Various modifications and changes may be made to the principles described herein without following the example embodiments and applications illustrated and described herein, and without departing from the spirit and scope of the disclosure. For example, unless otherwise explicitly indicated, the steps of a process or method may be performed in an order other than the example embodiments discussed above. Likewise, unless otherwise indicated, various components may be omitted, substituted, or arranged in a configuration other than the example embodiments discussed above.

Further aspects of the present disclosure are provided by the subject matter of the following clauses.

A method comprising: receiving, at a computer system, a plurality of first data streams associated, wherein data within the plurality of first data streams do not overlap temporally; blending, via at least one processor of the computer system, the plurality of first data streams, resulting in a first data stream blend; executing, via the at least one processor, an AI model using inputs comprising the first data stream blend, resulting an AI model data stream; blending, via the at least one processor, the AI model data stream with sensor data, resulting in combined prediction data.

A method comprising: generating, via at least one processor of a computer system using a first hydrology model for a predefined hydrologic unit, a runoff volumetric forecast; executing, via the at least one processor, a transport model of the predefined hydrologic unit, resulting in a first hydrograph; receiving, at the computer system, a flow volumetric report for the predefined hydrologic unit; executing, via the at least one processor, the transport model of the predefined hydrologic unit using the flow volumetric report, resulting in a second hydrograph; receiving, at the computer system, a flow volumetric forecast for the predefined hydrologic unit; generating, via the at least one processor, a third hydrograph of the predefined hydrologic unit using the flow volumetric forecast as input; comparing, via the at least one processor, the first hydrograph, the second hydrograph, and the third hydrograph to one another, resulting in a short term correction matrix; and modifying, via the at least one processor, the first hydrology model based on the short term correction matrix.

The method of any preceding clause, wherein the comparing of the first hydrograph, the second hydrograph, and the third hydrograph to one another further results in a long term correction matrix.

The method of any preceding clause, further comprising: modifying, via the at least one processor, a second level hydrology model based on the long term correction matrix.

The method of any preceding clause, wherein the comparing of the first hydrograph, the second hydrograph, and the third hydrograph to one another further comprises at least one of: identifying a distinct peak water level within the first hydrograph, the second hydrograph, and the third hydrograph; identifying a distinct breadth of water level within the first hydrograph, the second hydrograph, and the third hydrograph; and identifying a distinct water retreat time period within the first hydrograph, the second hydrograph, and the third hydrograph.

The method of any preceding clause, wherein the flow volumetric report is based on sensor data collected from a plurality of sensors, such that the second hydrograph is based on the sensor data.

The method of any preceding clause, wherein the first hydrograph and the second hydrograph are continuous predictions of hydrologic conditions, and wherein the second hydrograph is periodic based upon collection of the sensor data.

The method of any preceding clause, wherein the predefined hydrologic unit is a HUC 8.

A system comprising: at least one processor; and a non-transitory computer-readable storage medium having instructions stored which, when executed by the at least one processor, cause the at least one processor to perform operations comprising: generating, using a first hydrology model for a predefined hydrologic unit, a runoff volumetric forecast; executing a transport model of the predefined hydrologic unit, resulting in a first hydrograph[; receiving a flow volumetric report for the predefined hydrologic unit; executing the transport model of the predefined hydrologic unit using the flow volumetric report, resulting in a second hydrograph; receiving a flow volumetric forecast for the predefined hydrologic unit; generating a third hydrograph of the predefined hydrologic unit using the flow volumetric forecast as input; comparing the first hydrograph, the second hydrograph, and the third hydrograph to one another, resulting in a short term correction matrix; and modifying the first hydrology model based on the short term correction matrix.

The system of any preceding clause, wherein the comparing of the first hydrograph, the second hydrograph, and the third hydrograph to one another further results in a long term correction matrix.

The system of any preceding clause, the non-transitory computer-readable storage medium having additional instructions stored which, when executed by the at least one processor, cause the at least one processor to perform operations comprising: modifying a second level hydrology model based on the long term correction matrix.

The system of any preceding clause, wherein the comparing of the first hydrograph, the second hydrograph, and the third hydrograph to one another further comprises at least one of: identifying a distinct peak water level within the first hydrograph, the second hydrograph, and the third hydrograph; identifying a distinct breadth of water level within the first hydrograph, the second hydrograph, and the third hydrograph; and identifying a distinct water retreat time period within the first hydrograph, the second hydrograph, and the third hydrograph.

The system of any preceding clause, wherein the flow volumetric report is based on sensor data collected from a plurality of sensors, such that the second hydrograph is based on the sensor data.

The system of any preceding clause, wherein the first hydrograph and the second hydrograph are continuous predictions of hydrologic conditions, and wherein the second hydrograph is periodic based upon collection of the sensor data.

The system of any preceding clause, wherein the predefined hydrologic unit is a HUC 8.

A non-transitory computer-readable storage medium having instructions stored which, when executed by at least one processor, cause the at least one processor to perform operations comprising: generating, using a first hydrology model for a predefined hydrologic unit, a runoff volumetric forecast; executing a transport model of the predefined hydrologic unit, resulting in a first hydrograph; receiving a flow volumetric report for the predefined hydrologic unit; executing the transport model of the predefined hydrologic unit using the flow volumetric report, resulting in a second hydrograph; receiving a flow volumetric forecast for the predefined hydrologic unit; generating a third hydrograph of the predefined hydrologic unit using the flow volumetric forecast as input; comparing the first hydrograph, the second hydrograph, and the third hydrograph to one another, resulting in a short term correction matrix; and modifying the first hydrology model based on the short term correction matrix.

The non-transitory computer-readable storage medium of any preceding clause, wherein the comparing of the first hydrograph, the second hydrograph, and the third hydrograph to one another further results in a long term correction matrix.

The non-transitory computer-readable storage medium of any preceding clause, having additional instructions stored which, when executed by the at least one processor, cause the at least one processor to perform operations comprising: modifying a second level hydrology model based on the long term correction matrix.

The non-transitory computer-readable storage medium of any preceding clause, wherein the comparing of the first hydrograph, the second hydrograph, and the third hydrograph to one another further comprises at least one of: identifying a distinct peak water level within the first hydrograph, the second hydrograph, and the third hydrograph; identifying a distinct breadth of water level within the first hydrograph, the second hydrograph, and the third hydrograph; and identifying a distinct water retreat time period within the first hydrograph, the second hydrograph, and the third hydrograph.

The non-transitory computer-readable storage medium of any preceding clause, wherein the flow volumetric report is based on sensor data collected from a plurality of sensors, such that the second hydrograph is based on the sensor data.

The non-transitory computer-readable storage medium of any preceding clause, wherein the first hydrograph and the second hydrograph are continuous predictions of hydrologic conditions, and wherein the second hydrograph is periodic based upon collection of the sensor data.

We claim:

1. A method comprising:
generating, via at least one processor of a computer system using a first hydrology model for a predefined hydrologic unit, a runoff volumetric forecast;
executing, via the at least one processor, a transport model of the predefined hydrologic unit, resulting in a first hydrograph;
receiving, at the computer system, a flow volumetric report for the predefined hydrologic unit;
executing, via the at least one processor, the transport model of the predefined hydrologic unit using the flow volumetric report, resulting in a second hydrograph;
receiving, at the computer system, a flow volumetric forecast for the predefined hydrologic unit;
generating, via the at least one processor, a third hydrograph of the predefined hydrologic unit using the flow volumetric forecast as input;
comparing, via the at least one processor, the first hydrograph, the second hydrograph, and the third hydrograph to one another, resulting in a short term correction matrix; and
modifying, via the at least one processor, the first hydrology model based on the short term correction matrix.

2. The method of claim 1, wherein the comparing of the first hydrograph, the second hydrograph, and the third hydrograph to one another further results in a long term correction matrix.

3. The method of claim 2, further comprising:
modifying, via the at least one processor, a second level hydrology model based on the long term correction matrix.

4. The method of claim 1, wherein the comparing of the first hydrograph, the second hydrograph, and the third hydrograph to one another further comprises at least one of:
identifying a distinct peak water level within the first hydrograph, the second hydrograph, and the third hydrograph;
identifying a distinct breadth of water level within the first hydrograph, the second hydrograph, and the third hydrograph; and
identifying a distinct water retreat time period within the first hydrograph, the second hydrograph, and the third hydrograph.

5. The method of claim 1, wherein the flow volumetric report is based on sensor data collected from a plurality of sensors, such that the second hydrograph is based on the sensor data.

6. The method of claim 5, wherein the first hydrograph and the second hydrograph are continuous predictions of hydrologic conditions, and wherein the second hydrograph is periodic based upon collection of the sensor data.

7. The method of claim 1, wherein the predefined hydrologic unit is a HUC 8.

8. A system comprising:
at least one processor; and
a non-transitory computer-readable storage medium having instructions stored which, when executed by the at least one processor, cause the at least one processor to perform operations comprising:
generating, using a first hydrology model for a predefined hydrologic unit, a runoff volumetric forecast;
executing a transport model of the predefined hydrologic unit, resulting in a first hydrograph;
receiving a flow volumetric report for the predefined hydrologic unit;
executing the transport model of the predefined hydrologic unit using the flow volumetric report, resulting in a second hydrograph;
receiving a flow volumetric forecast for the predefined hydrologic unit;
generating a third hydrograph of the predefined hydrologic unit using the flow volumetric forecast as input;
comparing the first hydrograph, the second hydrograph, and the third hydrograph to one another, resulting in a short term correction matrix; and
modifying the first hydrology model based on the short term correction matrix.

9. The system of claim 8, wherein the comparing of the first hydrograph, the second hydrograph, and the third hydrograph to one another further results in a long term correction matrix.

10. The system of claim 9, the non-transitory computer-readable storage medium having additional instructions stored which, when executed by the at least one processor, cause the at least one processor to perform operations comprising:
modifying a second level hydrology model based on the long term correction matrix.

11. The system of claim 8, wherein the comparing of the first hydrograph, the second hydrograph, and the third hydrograph to one another further comprises at least one of:
identifying a distinct peak water level within the first hydrograph, the second hydrograph, and the third hydrograph;
identifying a distinct breadth of water level within the first hydrograph, the second hydrograph, and the third hydrograph; and
identifying a distinct water retreat time period within the first hydrograph, the second hydrograph, and the third hydrograph.

12. The system of claim 8, wherein the flow volumetric report is based on sensor data collected from a plurality of sensors, such that the second hydrograph is based on the sensor data.

13. The system of claim 12, wherein the first hydrograph and the second hydrograph are continuous predictions of hydrologic conditions, and wherein the second hydrograph is periodic based upon collection of the sensor data.

14. The system of claim 8, wherein the predefined hydrologic unit is a HUC 8.

15. A non-transitory computer-readable storage medium having instructions stored which, when executed by at least one processor, cause the at least one processor to perform operations comprising:
generating, using a first hydrology model for a predefined hydrologic unit, a runoff volumetric forecast;
executing a transport model of the predefined hydrologic unit, resulting in a first hydrograph;
receiving a flow volumetric report for the predefined hydrologic unit;
executing the transport model of the predefined hydrologic unit using the flow volumetric report, resulting in a second hydrograph;
receiving a flow volumetric forecast for the predefined hydrologic unit;
generating a third hydrograph of the predefined hydrologic unit using the flow volumetric forecast as input;
comparing the first hydrograph, the second hydrograph, and the third hydrograph to one another, resulting in a short term correction matrix; and
modifying the first hydrology model based on the short term correction matrix.

16. The non-transitory computer-readable storage medium of claim 15, wherein the comparing of the first hydrograph, the second hydrograph, and the third hydrograph to one another further results in a long term correction matrix.

17. The non-transitory computer-readable storage medium of claim 16, having additional instructions stored which, when executed by the at least one processor, cause the at least one processor to perform operations comprising:
modifying a second level hydrology model based on the long term correction matrix.

18. The non-transitory computer-readable storage medium of claim 15, wherein the comparing of the first hydrograph, the second hydrograph, and the third hydrograph to one another further comprises at least one of:
identifying a distinct peak water level within the first hydrograph, the second hydrograph, and the third hydrograph;
identifying a distinct breadth of water level within the first hydrograph, the second hydrograph, and the third hydrograph; and
identifying a distinct water retreat time period within the first hydrograph, the second hydrograph, and the third hydrograph.

19. The non-transitory computer-readable storage medium of claim 15, wherein the flow volumetric report is based on sensor data collected from a plurality of sensors, such that the second hydrograph is based on the sensor data.

20. The non-transitory computer-readable storage medium of claim 19, wherein the first hydrograph and the second hydrograph are continuous predictions of hydrologic conditions, and wherein the second hydrograph is periodic based upon collection of the sensor data.
